(19) United States
(12) Patent Application Publication
(10) Pub. No.: US 2011/0170265 A1
(43) Pub. Date: Jul. 14, 2011

(54) HEAT DISSIPATING DEVICE AND HEAT DISSIPATING SYSTEM

(76) Inventors: Jeng-Ming Lai, Taipei Hsien (TW); Shih-Huai Cho, Taipei Hsien (TW); Wei-Chung Hsiao, Taipei Hsien (TW); Chuan-Yi Liang, Taipei Hsien (TW); Yi-Jiun Lin, Taipei Hsien (TW)

(21) Appl. No.: 12/891,816

(22) Filed: Sep. 28, 2010

(30) Foreign Application Priority Data
Jan. 11, 2010 (TW) 099100610

(51) Int. Cl. H05K 7/20

(52) U.S. Cl. 361/709

(57) ABSTRACT

A heat dissipating device includes a supporting component installed on a circuit board. A plurality of openings is formed on the supporting component. The heat dissipating device further includes a plurality of heat dissipating components disposed on a side of the supporting component and installed inside the plurality of openings respectively for dissipating heat generated by a plurality of heat sources disposed on the other side of the supporting component. The heat dissipating device further includes a plurality of elastic components for pressing the plurality of heat dissipating components so that the plurality of heat dissipating components contacts the plurality of heat sources closely.

### BACKGROUND OF THE INVENTION

1. Field of the Invention

The present invention relates to a heat dissipating device and a heat dissipating system, and more specifically, to a heat dissipating device for dissipating heat generated by a plurality of heat sources and a heat dissipating system.

2. Description of the Prior Art

With the improvement of technology, consumer electronic products have a great diversity of functions, thus the demand of efficiency is getting higher. However, high efficiency means high energy consumption and even causes drawbacks of resonance, noise, overheat and so on. For example, heat generated by executing all kinds of functions will increase with high operational efficiency. If heat generated by inner components of the electronic products can not be dissipated efficiently, it will affect operating stability and operating efficiency and even results in mechanical malfunction and damage. In current industry, a heat dissipating system is added to solve the problem, such as a fan, a heat sink, a heat pipe, a thermal pad, a cooling chip, and so on, for cooling the components, so as to keep stability of the electronic products.

Since many processing chips are disposed on a motherboard of a computer system, an air-cooling heat dissipating module is usually applied for dissipating heat generated by the processing chips. As for a fixing mechanism for fixing the heat dissipating module, a hook of the heat dissipating module is usually utilized to hook an anchor structure of the motherboard, or a spring screw is utilized to screw the heat dissipating module to the motherboard. However, when neighboring processing chips are disposed closely, special mechanical design is needed. For example, if many heat dissipating devices are utilized simultaneously to dissipate heat generated by the processing chips respectively, hooks or spring screws are used for fixing each heat dissipating device respectively, thus a lot of corresponding anchor structures or slots are disposed on the motherboard accordingly. It results in space limitation and high cost due to multilayer layout for overcoming the space limitation of disposing the electrical components. On the other hand, if a single large heat dissipating device is utilized to dissipate heat generated by all processing chips simultaneously, it can overcome the above-mentioned problems of disposition of anchor structures or slots though, but since there is a height difference between the processing chips due to assembly tolerance, so as to cause poor contact between the single large heat dissipating device and the processing chips. Thus, stepped finish of the contact surface or a thermal pad with high cost is required to overcome the poor contact problem. Therefore, it is an important issue to design a favorable dissipating mechanism for dissipating heat generated by a plurality of heat sources simultaneously.

### SUMMARY OF THE INVENTION

The present invention provides a heat dissipating device for dissipating heat generated by a plurality of heat sources and a heat dissipating system to solve the problems mentioned above.

According to the claimed invention, a heat dissipating device includes a supporting component installed on a circuit board, a plurality of openings is formed on the supporting component; a plurality of heat dissipating components disposed on a side of the supporting component and installed inside the plurality of openings respectively, the plurality of heat dissipating components is for dissipating heat generated by a plurality of heat sources disposed on the other side of the supporting component; and a plurality of elastic components for pressing the plurality of heat dissipating components so that the plurality of heat dissipating components contacts the plurality of heat sources closely.

According to the claimed invention, the supporting component is screwed to the circuit board.

According to the claimed invention, two ends of the elastic component are fixed to two sides of the supporting component respectively, and a middle part of the elastic component locks the heat dissipating component.

According to the claimed invention, the supporting component includes a base, the plurality of holes are formed on the base; and a plurality of lateral walls connected to the base respectively, two ends of the elastic component are fixed to the plurality of lateral walls respectively, and a middle part of the elastic component locks the heat dissipating component.

According to the claimed invention, the plurality of lateral walls is disposed on sides of the base.

According to the claimed invention, the plurality of lateral walls is disposed on a middle part of the base.

According to the claimed invention, one end of the elastic component is fixed to the supporting component and the other end of the elastic component is fixed to the circuit board, and a middle part of the elastic component locks the heat dissipating component.

According to the claimed invention, a groove is formed on the heat dissipating component for accommodating part of the elastic component pressing the heat dissipating component.

According to the claimed invention, a heat dissipating system includes a circuit board; a plurality of heat sources installed on the circuit board respectively; and a heat dissipating device for dissipating heat generated by a plurality of heat sources. The heat dissipating device includes a supporting component installed on a circuit board, a plurality of openings is formed on the supporting component; a plurality of heat dissipating components disposed on a side of the supporting component and installed inside the plurality of openings respectively, the plurality of heat dissipating components is for dissipating heat generated by a plurality of heat sources disposed on the other side of the supporting component; and a plurality of elastic components for pressing the plurality of heat dissipating components so that the plurality of heat dissipating components contacts the plurality of heat sources closely.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded diagram of a heat dissipating system according to a first preferred embodiment of the present invention.

FIG. 2 is an assembly diagram of the heat dissipating system according to the first preferred embodiment of the present invention.

FIG. 3 is a top view of the heat dissipating system according to the first preferred embodiment of the present invention.

FIG. 4 is a side view of the heat dissipating system according to the first preferred embodiment of the present invention.

FIG. 5 is an exploded diagram of a heat dissipating system according to a second preferred embodiment of the present invention.

FIG. 6 is an assembly diagram of the heat dissipating system according to the second preferred embodiment of the present invention.

FIG. 7 is a top view of the heat dissipating system according to the second preferred embodiment of the present invention.

FIG. 8 is a side view of the heat dissipating system according to the second preferred embodiment of the present invention.

FIG. 9 is an exploded diagram of a heat dissipating system according to a third preferred embodiment of the present invention.

FIG. 10 is an assembly diagram of the heat dissipating system according to the third preferred embodiment of the present invention.

FIG. 11 is a top view of the heat dissipating system according to the third preferred embodiment of the present invention.

FIG. 12 is a side view of the heat dissipating system according to the third preferred embodiment of the present invention.

### DETAILED DESCRIPTION

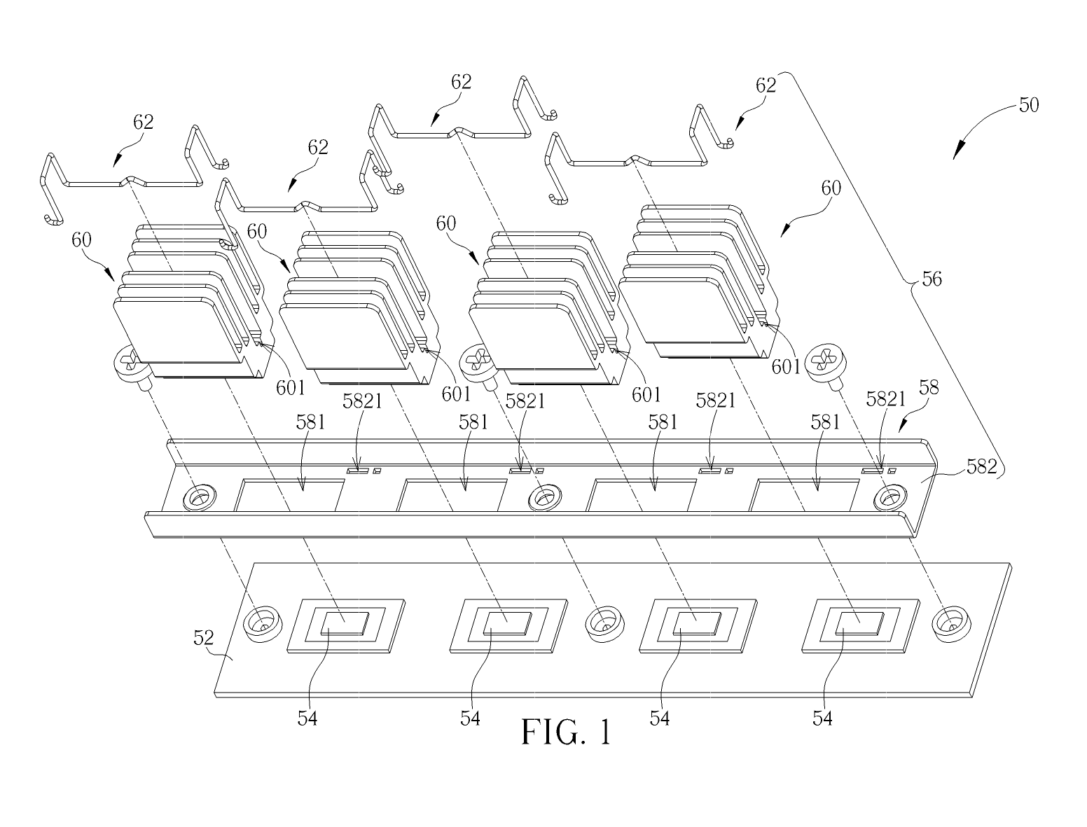

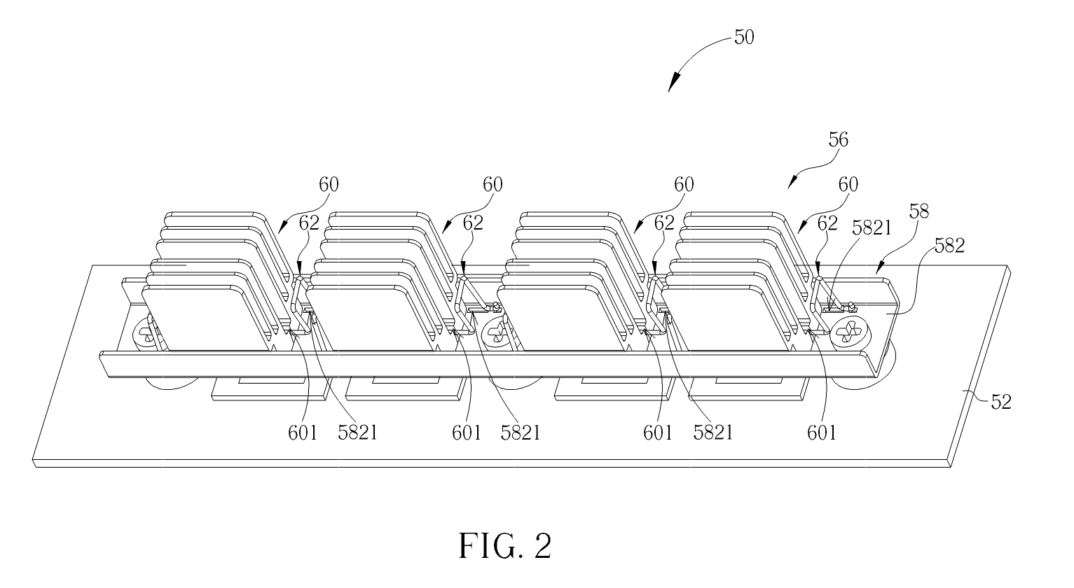

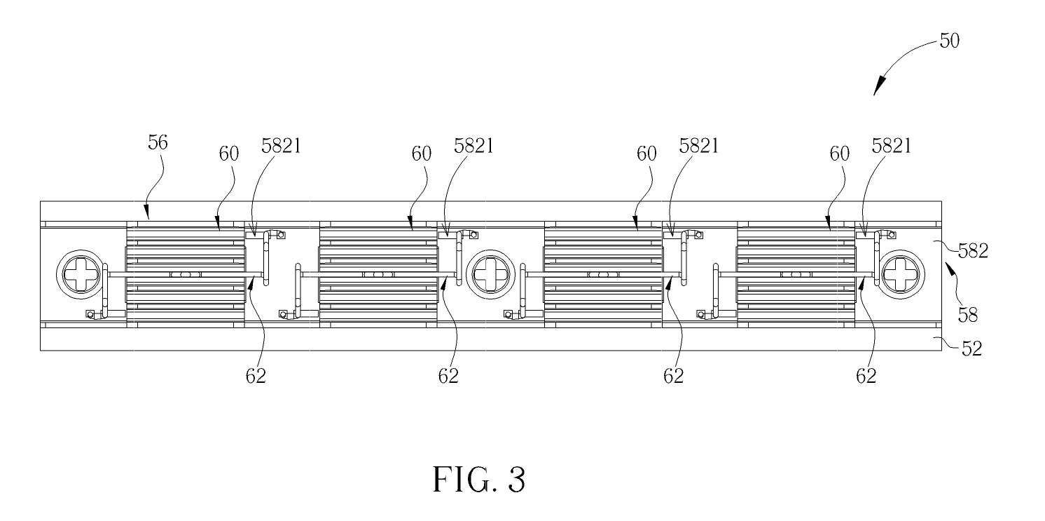

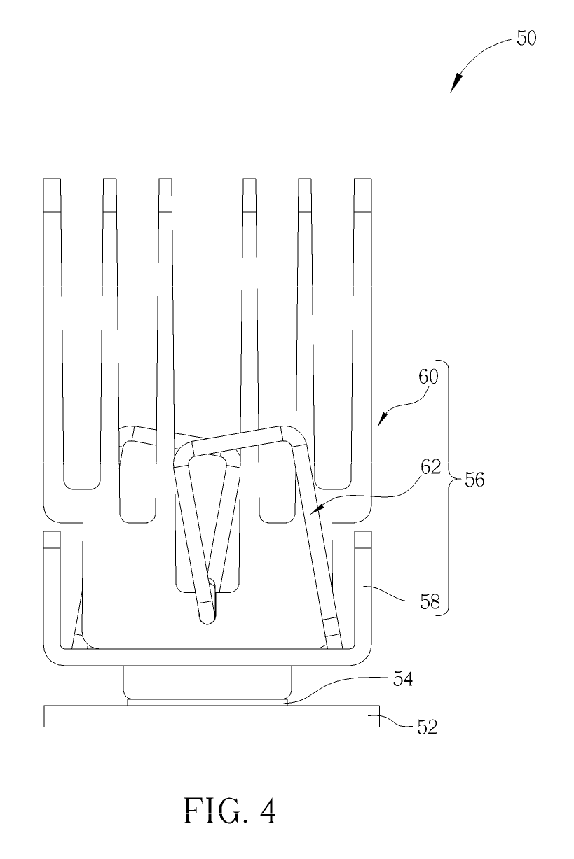

Please refer to FIG. 1 to FIG. 4. FIG. 1 is an exploded diagram of a heat dissipating system 50 according to a first preferred embodiment of the present invention. FIG. 2 is an assembly diagram of the heat dissipating system 50 according to the first preferred embodiment of the present invention. FIG. 3 is a top view of the heat dissipating system 50 according to the first preferred embodiment of the present invention. FIG. 4 is a side view of the heat dissipating system 50 according to the first preferred embodiment of the present invention. The heat dissipating system 50 can be applied in a computer. The heat dissipating system 50 includes a circuit board 52, which can be a motherboard. The heat dissipating system 50 further includes a plurality of heat sources 54 installed on the circuit board 52 respectively, and the heat source 54 can be a processing chip and son on. The heat dissipating system 50 further includes a heat dissipating device 56 for dissipating heat generated by a plurality of heat sources 54. The heat dissipating device 56 includes a supporting component 58 installed on the circuit board 52. For example, the supporting component 58 can be screwed to the circuit board 52. A plurality of openings 581 is formed on the supporting component 58. The supporting component 58 can be a structure including a base and a lateral wall or can be a flat structure, and it depends on practical design demand. The heat dissipating device 56 further includes a plurality of heat dissipating components 60 disposed on a side of the supporting component 58 and installed inside the plurality of openings 581 respectively. The plurality of heat dissipating components 60 passes through the plurality of openings 581 respectively and contacts the plurality of heat sources 54 respectively, for dissipating heat generated by the plurality of heat sources 54 disposed on the other side of the supporting component 58. The heat dissipating component 60 can be a thermal fin. A groove 601 is formed on each heat dissipating component 60. The heat dissipating device 56 further includes a plurality of elastic components 62 for pressing the plurality of heat dissipating components 60 so that the plurality of heat dissipating components 60 contacts the plurality of heat sources 54 closely. The groove 601 of the heat dissipating component 60 is for accommodating part of the elastic component 62 pressing the heat dissipating component 60. The elastic component 62 can be a fastening clip or any other elastic fastening component.

In this embodiment, two ends of each elastic component 62 are fixed to two sides of the supporting component 58 respectively, such as being hooked inside a plurality of first slots 5821 of two sides of a base 582 of the supporting component 58, and the middle part of each elastic component 62 locks the corresponding heat dissipating component 60. The heat dissipating component 60 can be pressed by a pressing force of the elastic component 62 to ensure that the heat dissipating component 60 contacts the heat source 54 closely, so as to improve heat dissipating efficiency of the heat dissipating component 60. Furthermore, a pressing force applied for the heat dissipating component 60 can be adjusted by adjusting the shape of each elastic component 62 or the locking position of the supporting component 58, for achieving the best contact between the heat dissipating component 60 and the heat source 54 by adjusting the arrangement of the corresponding elastic component 62 so as to improve poor contact. Besides, the present invention can utilize the same kind of elastic component 62 to fasten different kinds of heat dissipating component 60 by adjusting the arrangement of the elastic component 62, such that it can economize manufacture cost and increase assembly convenience. In this embodiment, the supporting component 58 can be screwed on the circuit board 52, and two ends of each elastic component 62 are fixed to two sides of the supporting component 58 respectively. Furthermore, one end of the elastic component 62 can be fixed to the supporting component 58, the other end of the elastic component 62 can be fixed to the circuit board 52, and the middle part of the elastic component 62 locks the heat dissipating component 60, such that the supporting component 58 can be fixed to the circuit board 52 by the elastic component 62 without utilizing additional fastening mechanism to fix the supporting component 58 to the circuit board 52.

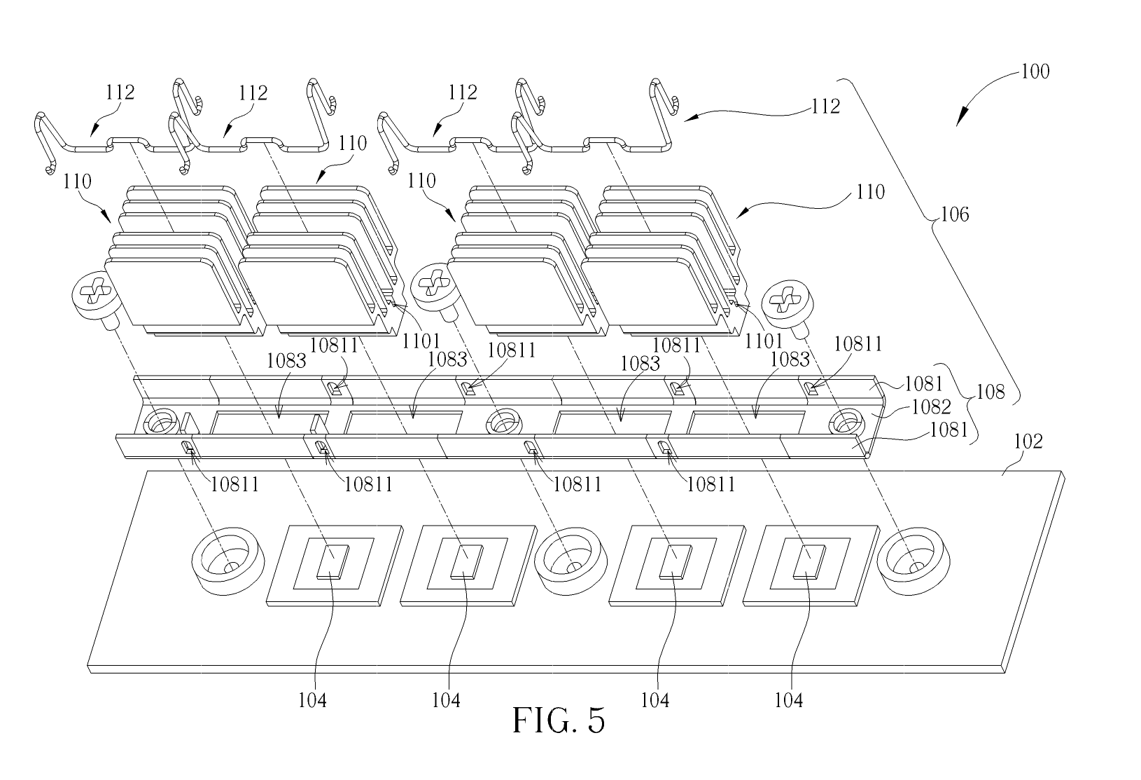

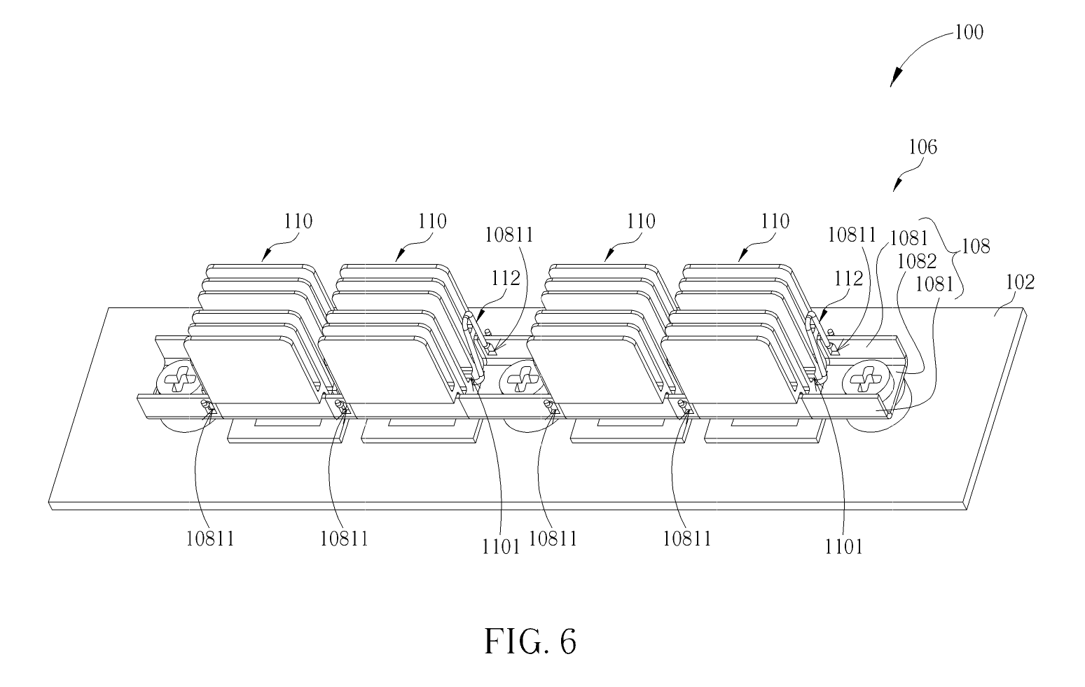

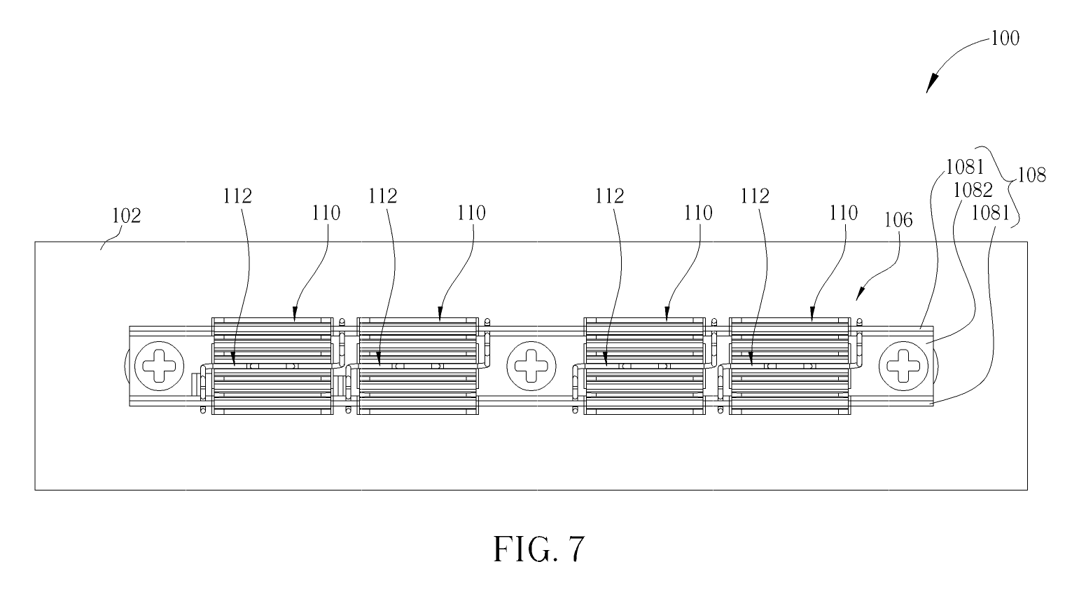

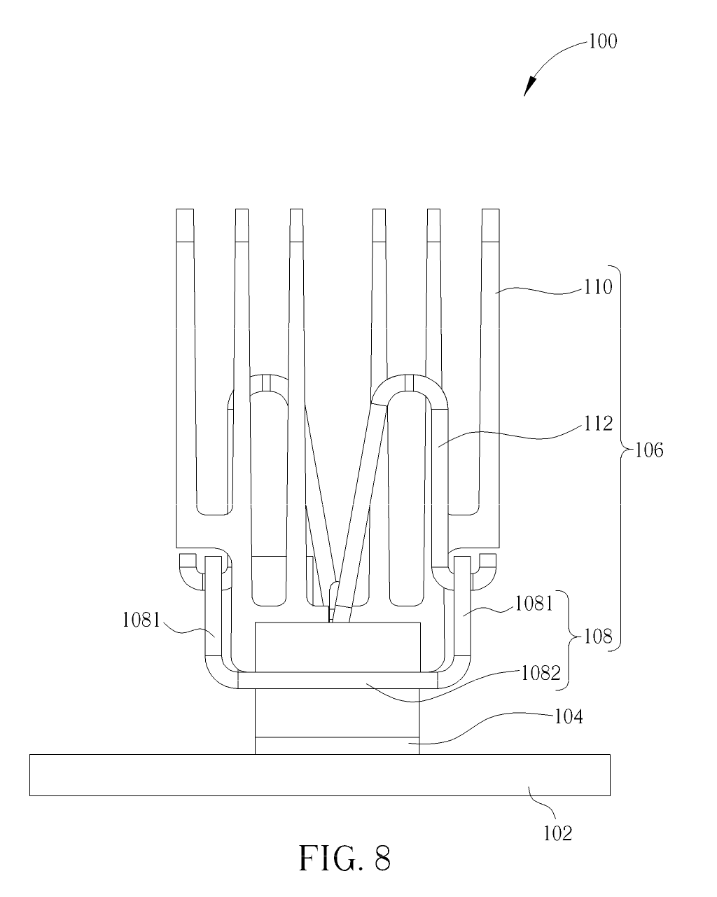

Please refer to FIG. 5 to FIG. 8. FIG. 5 is an exploded diagram of a heat dissipating system 100 according to a second preferred embodiment of the present invention. FIG. 6 is an assembly diagram of the heat dissipating system 100 according to the second preferred embodiment of the present invention. FIG. 7 is a top view of the heat dissipating system 100 according to the second preferred embodiment of the present invention. FIG. 8 is a side view of the heat dissipating system 100 according to the second preferred embodiment of the present invention. The heat dissipating system 100 can be applied in a computer. The heat dissipating system 100 includes a circuit board 102, which can be a motherboard. The heat dissipating system 100 further includes a plurality of heat sources 104 installed on the circuit board 102 respectively, and the heat source 104 can be a processing chip and son on. The heat dissipating system 100 further includes a heat dissipating device 106 for dissipating heat generated by a plurality of heat sources 104. The heat dissipating device 106 includes a supporting component 108 installed on the circuit board 102. For example, the supporting component 108 can be screwed to the circuit board 102. The supporting component 108 includes two lateral walls 1081, and a base 1082. The base 1082 is connected to the two lateral walls 1081. The two lateral walls 1081 are disposed on lateral sides of the base 1082. A plurality of openings 1083 is formed on the base 1082. The heat dissipating device 106 further includes a plurality of heat dissipating components 110 disposed on a side of the supporting component 108 and installed inside the plurality of openings 1083 respectively. The plurality of heat dissipating components 110 passes through the plurality of openings 1083 respectively and contacts the plurality of heat sources 104 respectively, for dissipating heat generated by the plurality of heat sources 104 disposed on the other side of the supporting component 108. The heat dissipating component 110 can be a thermal fin. A groove 1101 is formed on each heat dissipating component 110. The heat dissipating device 106 further includes a plurality of elastic components 112 for pressing the plurality of heat dissipating components 110 so that the plurality of heat dissipating components 110 contacts the plurality of heat sources 104 closely. The groove 1101 of the heat dissipating component 110 is for accommodating part of the elastic component 112 pressing the heat dissipating component 110. The elastic component 112 can be a fastening clip or any other elastic fastening component. The difference between the first embodiment and the second embodiment is that two ends of the elastic component 112 is fixed to two sides of the lateral wall 1081 respectively, such as being hooked inside a plurality of second slots 10811 of two sides of the later wall 1081, and the middle part of the elastic component 112 locks the heat dissipating component 110. The heat dissipating component 110 can be pressed by a pressing force of the elastic component 112 to ensure that the heat dissipating component 110 contacts the heat source 104 closely, so as to improve heat dissipating efficiency of the heat dissipating component 110. As for that the other working principle of the second embodiment is identical to the first embodiment, so it will not be depicted herein.

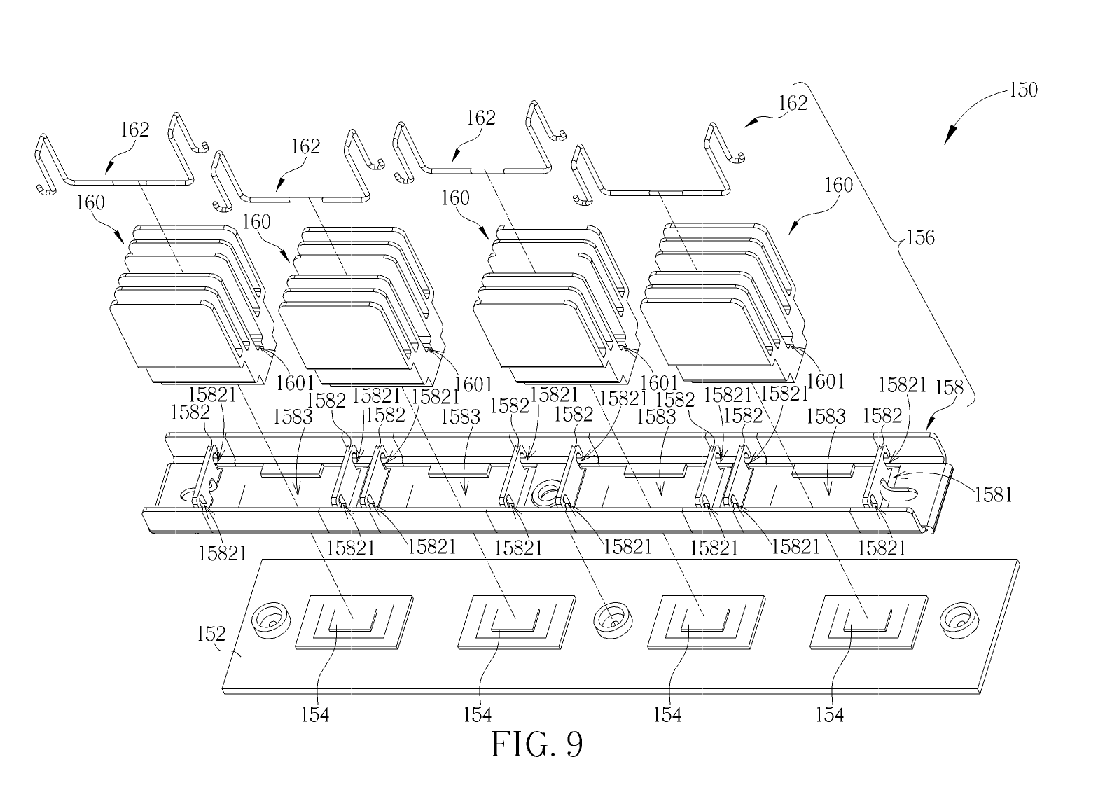

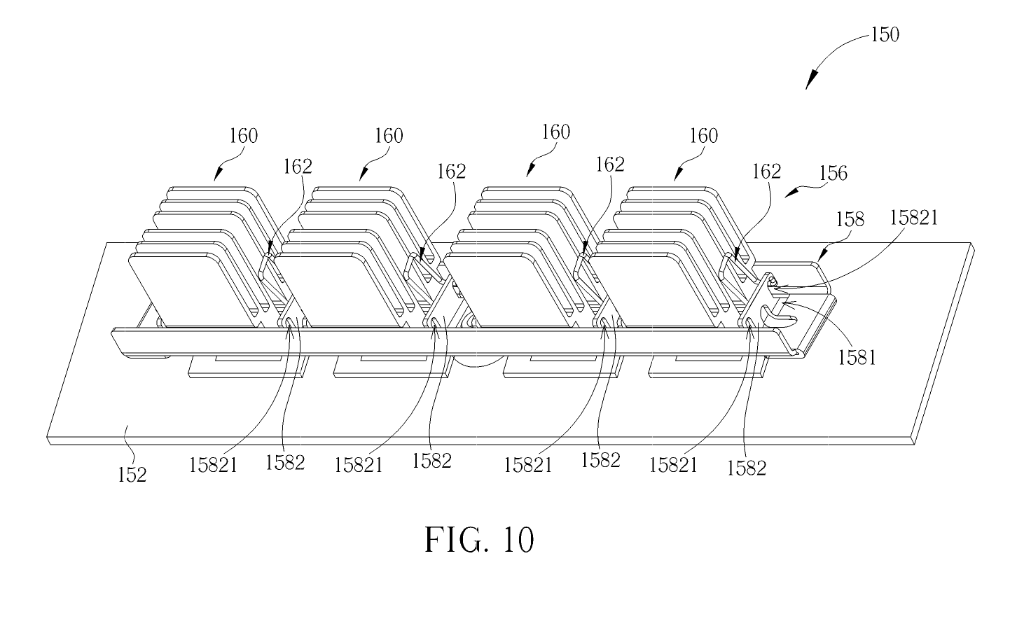

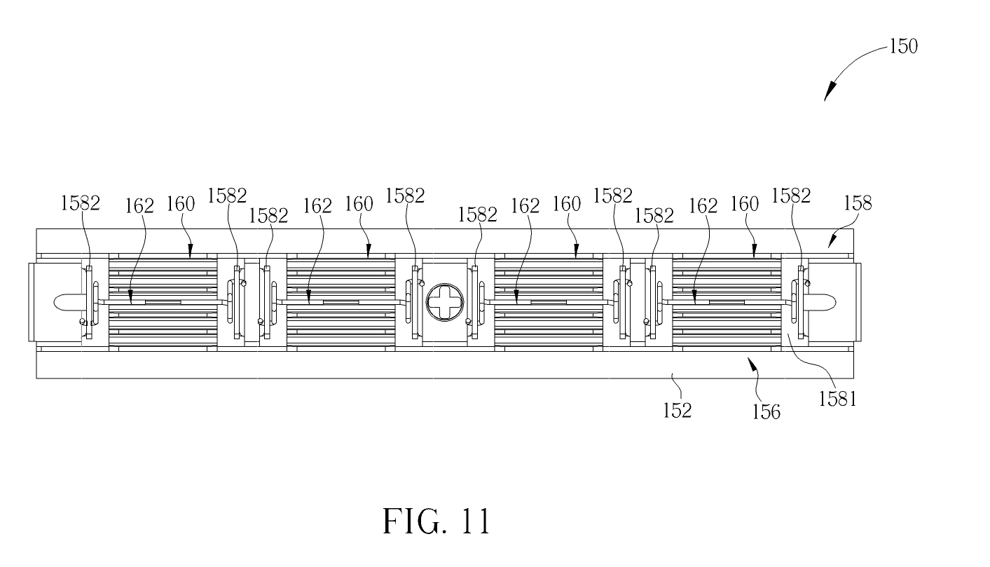

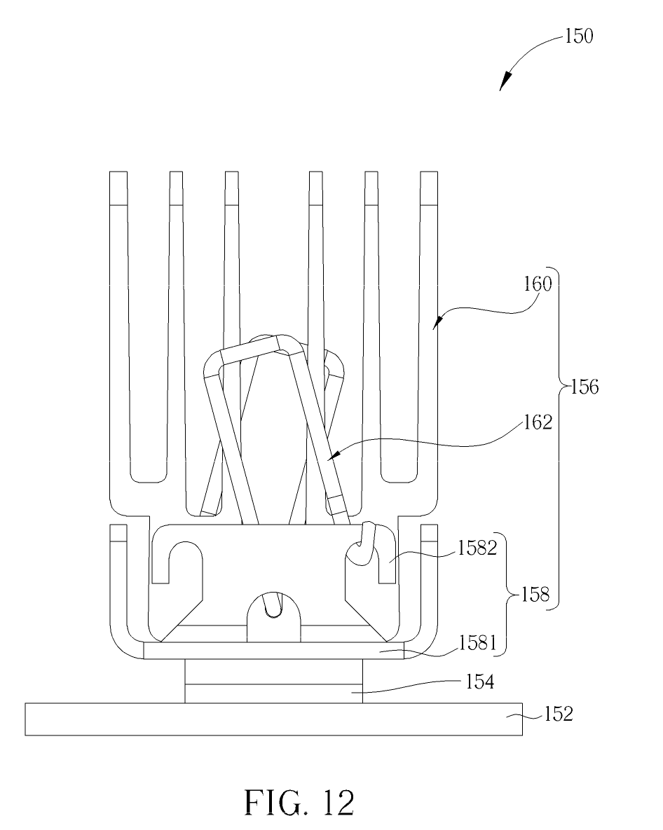

Please refer to FIG. 9 to FIG. 12, FIG. 9 is an exploded diagram of a heat dissipating system 150 according to a third preferred embodiment of the present invention. FIG. 10 is an assembly diagram of the heat dissipating system 150 according to the third preferred embodiment of the present invention. FIG. 11 is a top view of the heat dissipating system 150 according to the third preferred embodiment of the present invention. FIG. 12 is a side view of the heat dissipating system 150 according to the third preferred embodiment of the present invention. The heat dissipating system 150 can be applied in a computer. The heat dissipating system 150 includes a circuit board 152, which can be a motherboard. The heat dissipating system 150 further includes a plurality of heat sources 154 installed on the circuit board 152 respectively, and the heat source 154 can be a processing chip and son on. The heat dissipating system 150 further includes a heat dissipating device 156 for dissipating heat generated by a plurality of heat sources 154. The heat dissipating device 156 includes a supporting component 158 installed on the circuit board 152. For example, the supporting component 158 can be screwed to the circuit board 152. The supporting component 158 includes a plurality of lateral walls 1582, and a base 1581. The base 1581 is connected to the plurality of lateral walls 1582. The plurality of lateral walls 1582 is disposed on a middle part of the base 1581. A plurality of openings 1583 is formed on the base 1581. The heat dissipating device 156 further includes a plurality of heat dissipating components 160 disposed on a side of the supporting component 158 and installed inside the plurality of openings 1583 respectively. The plurality of heat dissipating components 160 passes through the plurality of openings 1583 respectively and contacts the plurality of heat sources 154 respectively, for dissipating heat generated by the plurality of heat sources 154 disposed on the other side of the supporting component 158. The heat dissipating component 160 can be a thermal fin. A groove 1601 is formed on each heat dissipating component 160. The heat dissipating device 156 further includes a plurality of elastic components 162 for pressing the plurality of heat dissipating components 160 so that the plurality of heat dissipating components 160 contacts the plurality of heat sources 154 closely. The groove 1601 of the heat dissipating component 160 is for accommodating part of the elastic component 162 pressing the heat dissipating component 160. The elastic component 162 can be a fastening clip or any other elastic fastening component. The difference between the third embodiment and the aforesaid embodiments is that two ends of the elastic component 162 is fixed to two sides of the lateral wall 1582 of the heat dissipating component 160 correspondingly, such as being hooked inside a plurality of third slots 15821 of two sides of the later wall 1582, and the middle part of the elastic component 162 locks the heat dissipating component 160. The heat dissipating component 160 can be pressed by a pressing force of the elastic component 162 to ensure that the heat dissipating component 160 contacts the heat source 154 closely, so as to improve heat dissipating efficiency of the heat dissipating component 160. As for that the other working principle of the third embodiment is identical to the aforesaid embodiments, so it will not be depicted herein.

Compared to the prior art, the present invention provides the heat dissipating device for dissipating heat generated by the plurality of heat sources and the heat dissipating system, and the pressing force between the heat dissipating components and the heat sources can be adjusted by adjusting the shape or the arrangement of the elastic component, for achieving the best contact between the heat dissipating component and the heat source by adjusting the arrangement of the corresponding elastic component so as to improve poor contact. Furthermore, the present invention also solves the problem that a lot of anchor structures or slots are required to fasten the plurality of the heat dissipating components on the motherboard in the prior art, so as to increase design flexibility of the motherboard. Therefore, the present invention provides a favorable design of the heat dissipating mechanism for dissipating heat generated by the plurality of heat sources simultaneously.

Those skilled in the art will readily observe that numerous modifications and alterations of the device and method may be made while retaining the teachings of the invention.

What is claimed is:

1. A heat dissipating device comprising:
a supporting component installed on a circuit board, a plurality of openings being formed on the supporting component;
a plurality of heat dissipating components disposed on a side of the supporting component and installed inside the plurality of openings respectively, the plurality of heat dissipating components being for dissipating heat generated by a plurality of heat sources disposed on the other side of the supporting component; and
a plurality of elastic components for pressing the plurality of heat dissipating components so that the plurality of heat dissipating components contacts the plurality of heat sources closely.

2. The heat dissipating device of claim 1, wherein the supporting component is screwed to the circuit board.

3. The heat dissipating device of claim 1, wherein two ends of the elastic component are fixed to two sides of the supporting component respectively, and a middle part of the elastic component locks the heat dissipating component.

4. The heat dissipating device of claim 3, wherein the supporting component comprises:
a base, the plurality of holes being formed on the base; and
a plurality of lateral walls connected to the base respectively, two ends of the elastic component being fixed to the plurality of lateral walls respectively, and a middle part of the elastic component locking the heat dissipating component.

5. The heat dissipating device of claim 4, wherein the plurality of lateral walls is disposed on sides of the base.

6. The heat dissipating device of claim 4, wherein the plurality of lateral walls is disposed on a middle part of the base.

7. The heat dissipating device of claim 1, wherein one end of the elastic component is fixed to the supporting component and the other end of the elastic component is fixed to the circuit board, and a middle part of the elastic component locks the heat dissipating component.

8. The heat dissipating device of claim 1, wherein a groove is formed on the heat dissipating component for accommodating part of the elastic component pressing the heat dissipating component.

9. A heat dissipating system including:
a circuit board;
a plurality of heat sources installed on the circuit board respectively; and
a heat dissipating device including:
a supporting component installed on the circuit board, a plurality of openings being formed on the supporting component;
a plurality of heat dissipating components disposed on a side of the supporting component and installed inside the plurality of openings respectively, the plurality of heat dissipating components being for dissipating heat generated by the plurality of heat sources disposed on the other side of the supporting component; and
a plurality of elastic components for pressing the plurality of heat dissipating components so that the plurality of heat dissipating components contacts the plurality of heat sources closely.

10. The heat dissipating system of claim 9, wherein the supporting component is screwed to the circuit board.

11. The heat dissipating system of claim 10, wherein two ends of the elastic component are fixed to two sides of the supporting component respectively, and a middle part of the elastic component locks the heat dissipating component.

12. The heat dissipating system of claim 11, wherein the supporting component comprises:
a base, the plurality of holes being formed on the base; and
a plurality of lateral walls connected to the base respectively, two ends of the elastic component are fixed to the plurality of lateral walls respectively, and a middle part of the elastic component locking the heat dissipating component.

13. The heat dissipating system of claim 12, wherein the plurality of lateral walls is disposed on sides of the base.

14. The heat dissipating system of claim 12, wherein the plurality of lateral walls is disposed on a middle part of the base.

15. The heat dissipating system of claim 9, wherein one end of the elastic component is fixed to the supporting component and the other end of the elastic component is fixed to the circuit board, and a middle part of the elastic component locks the heat dissipating component.

16. The heat dissipating system of claim 9, wherein a groove is formed on the heat dissipating component for accommodating part of the elastic component pressing the heat dissipating component.
